(19) United States
(12) Patent Application Publication
(10) Pub. No.: US 2004/0153911 A1
(43) Pub. Date: Aug. 5, 2004

(54) Testing of a CAM

(76) Inventors: Alon Regev, Woodland Hills, CA (US); Zvi Regev, West Hills, CA (US)

Correspondence Address: DICKSTEIN SHAPIRO MORIN & OSHINSKY LLP, 2101 L STREET NW, WASHINGTON, DC, 20037-1526, US

(21) Appl. No.: 10/327,045

(22) Filed: Dec. 24, 2002

(51) Int. Cl. G11C 29/00

(52) U.S. Cl. 714/718

(57) ABSTRACT

A system and method for validating a memory device using a Gray Code is described. The system and method tests data segments of a memory storage location concurrently, where a data segment may be a nibble. Each data segment cycles through the possible Gray Code states. Once a data segment, and therefore each data segment because of the concurrency, cycles through the possible Gray code states, the memory device is completely tested. A memory device may, in particular, be a content addressable memory (CAM). A method for testing a priority encoder of a CAM using a Gray Code is also described. Each memory storage location is loaded with a predetermined Gary code representing the address of the memory storage location, each memory storage location differs from an adjacent memory storage location by one data bit.

### FIELD OF THE INVENTION

The present invention relates generally to memory devices and in particular to a system and method for testing memory devices, in particular, content addressable memory (CAM) devices, and priority encoders for CAMs.

### BACKGROUND OF THE INVENTION

Testing of memory devices is extremely time consuming and costly. Testing, however, is necessary to identify errors. If errors are not identified data could become corrupted. In particular, data in CAMs is often used to access addresses in networks and information and data to be sent may be misdirected with results ranging from non-delivery to mis-delivery. In testing CAMs, it is customary to write data into the CAM memory storage locations in the form of successive numbers, presented in binary code.

In conventional testing of a priority encoder, the CAM memory has to be loaded multiple times. The number of times that the CAM memory has to be loaded is typically equivalent to the number of bits in the priority encoder output. That is, if a priority encoder has ten output bits the CAM memory has to be loaded ten times. Part of the priority encoder test requires comparing two adjacent words. Using a binary representation of numbers requires several bits in the comparand register to be masked to cause the adjacent words to match with the masked comparand.

### SUMMARY OF THE INVENTION

The present invention provides a system and method that shortens the time to test memory storage locations of memory devices, in particular CAMs and thus, reduce costs. In the present invention the CAM is loaded with data presented in Gray Code, wherein two successive data segments always differ by only a single bit.

The present invention also provides a system and method for testing a priority encoder of a CAM. Using Gray Code, only one bit of data in the comparand needs to be masked for two adjacent/successive memory storage locations to match the contents of the comparand. The advantage of the method of the present invention is that the CAM memory only has to be loaded with one set of data to conduct all the priority encoder tests described herein. The present invention, thus, translates into a significant reduction in test time and cost.

### BRIEF DESCRIPTION OF THE DRAWINGS

FIG. 1 is a finite state diagram of the Gray Code for a nibble employed in the present invention;

FIG. 2a is a nibble;

FIG. 2b is a word;

FIG. 3a is a pair of words of eight nibbles each, the first word starting with Gray Code state q0 as the first nibble of the present invention;

FIG. 3b is a pair of words of eight nibbles each, the first word starting with Gray Code state q1 in the first nibble of the present invention;

FIG. 3c is a pair of words of eight nibbles each, the first word starting with Gray Code state q3 in the first nibble of the present invention;

FIG. 3d is a pair of words of eight nibbles each, the first word starting with Gray Code state q2 in the first nibble of the present invention;

FIG. 3e is a pair of words of eight nibbles each, the first word starting with Gray Code state q6 in the first nibble of the present invention;

FIG. 3f is a pair of words of eight nibbles each, the first word starting with Gray Code state q7 in the first nibble of the present invention;

FIG. 3g is a pair of words of eight nibbles each, the first word starting with Gray Code state q5 in the first nibble of the present invention;

FIG. 3h is a pair of words of eight nibbles each, the first word starting with Gray Code state q4 in the first nibble of the present invention;

FIG. 3i is a pair of words of eight nibbles each, the first word starting with Gray Code state q12 in the first nibble of the present invention;

FIG. 3j is a pair of words of eight nibbles each, the first word starting with Gray Code state q13 in the first nibble of the present invention;

FIG. 3k is a pair of words of eight nibbles each, the first word starting with Gray Code state q15 in the first nibble of the present invention;

FIG. 3l is a pair of words of eight nibbles each, the first word starting with Gray Code state q14 in the first nibble of the present invention;

FIG. 3m is a pair of words of eight nibbles each, the first word starting with Gray Code state q10 in the first nibble of the present invention;

FIG. 3n is a pair of words of eight nibbles each, the first word starting with Gray Code state q11 in the first nibble of the present invention;

FIG. 3o is a pair of words of eight nibbles each, the first word starting with Gray Code state q9 in the first nibble of the present invention;

FIG. 3p is a pair of words of eight nibbles each, the first word starting with Gray Code state q8 in the first nibble of the present invention;

FIG. 3q is an exemplary embodiment of Gray Code state 0 (q0) of the present invention;

FIG. 4 is an exemplary CAM layout of the present invention;

FIG. 5a is a flowchart of the method for testing a CAM in accordance with the present invention;

FIG. 5b is a flowchart of the error processing depicted in FIG. 5a;

FIG. 6 is a block diagram of a system for testing a CAM;

FIG. 7 is an exemplary highest priority indicator of a priority encoder of a CAM of the present invention;

FIG. 8 is an exemplary address encoder of the present invention;

FIG. 9a is an exemplary method for testing a priority encoder of a CAM using the present invention;

FIG. 9b is an alternative exemplary method for testing a priority encoder of a CAM using the present invention; and

FIG. 10 is an exemplary computer system having a memory device tested in accordance with the present invention.

### DETAILED DESCRIPTION OF THE PREFERRED EMBODIMENTS

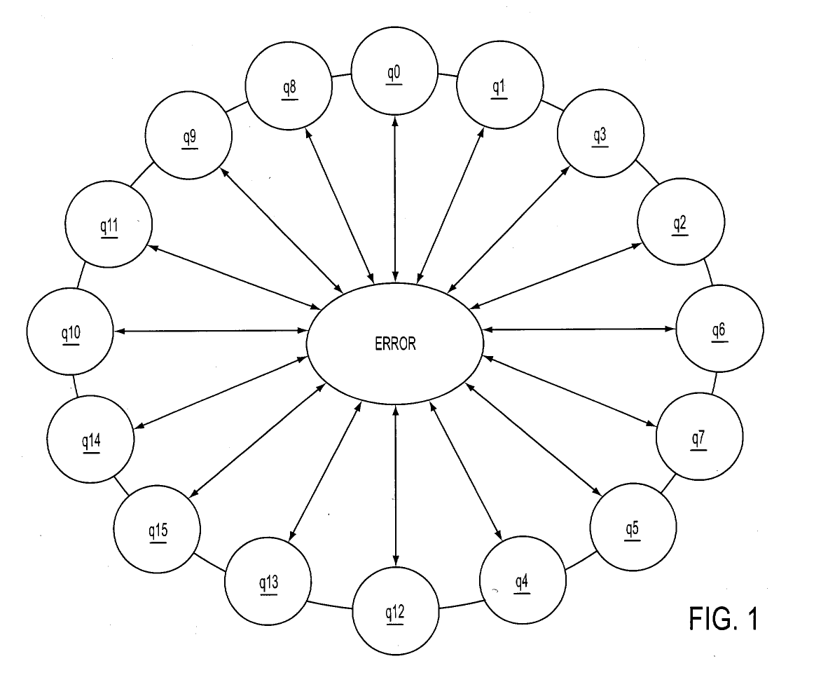

The present invention will be described in connection with exemplary embodiments illustrated in FIGS. 1-9. Other embodiments may be realized and other changes may be made to the disclosed embodiments without departing from the spirit or scope of the present invention. It should be noted, in particular, that CAM can be implemented as any form of RAM, e.g., SRAM, DRAM, PCRAM, MRAM, etc. and that the system and method described herein may be used to test any memory device.

The Gray Code is a reflective binary representation of numbers that corresponds to a single bit changing from a binary number to its successor. Table 1 presents numbers as decimal numbers (0-15), in binary format (four bits), in Gray Code and the corresponding Gray Code state.

TABLE 1

| | | | | Mask to go to |
|---|---|---|---|---|
| Number | Binary | Gray Code | State | next state |
| 0 | 0000 | 0000 | q0 | 000X |
| 1 | 0001 | 0001 | q1 | 00X0 |
| 2 | 0010 | 0011 | q3 | 001X |
| 3 | 0011 | 0010 | q2 | 0X10 |
| 4 | 0100 | 0110 | q6 | 011X |
| 5 | 0101 | 0111 | q7 | 01X1 |
| 6 | 0110 | 0101 | q5 | 010X |
| 7 | 0111 | 0100 | q4 | X100 |
| 8 | 1000 | 1100 | q12 | 110X |
| 9 | 1001 | 1101 | q13 | 11X1 |
| 10 | 1010 | 1111 | q15 | 111X |
| 11 | 1101 | 1110 | q14 | 1X10 |
| 12 | 1100 | 1010 | q10 | 101X |
| 13 | 1101 | 1011 | q11 | 10X1 |
| 14 | 1110 | 1001 | q9 | 100X |
| 15 | 1111 | 1000 | q8 | X000 |

The Gray Code is called a reflective code because if the above exemplary table is folded in half after the decimal number “7”, then other than the high order bit the codes reflect or mirror each other. That is, the number “8” is represented in Gray Code as “1100” and the number “7” is represented in Gray Code as “0100” with the last three bits of the two numbers being identical. Moving away from the fold, the same is true for “9” and “6” which differ only in the most significant bit in their Gray Code representations. The same would be true for a table of the decimal digits from zero to seven folded after the number “3”. That is, the number “3” represented by Gray Code “010” and the number “4” represented by Gray Code “110” only differ by the most significant bit. The same would be true extending the representation to five bits (decimal numbers 0-31) and folding the table after the number “15”. The last column of the table represents the states or translation of the Gray Code as a binary number. For example, the decimal number “2” is represented in binary as “0010” and in Gray Code as “0011” so the state would be “q3”, where the letter “q” is the designation for “state” and the number “3” is the translation of the Gray Code (“0011”) to a decimal number.

FIG. 1 is a finite state diagram for proceeding through the Gray code representation of decimal numbers 0-15, where “q0” represents Gray Code “0000”, “q1” represents Gray Code “0001”, “q3” represents Gray Code “0011”, etc. The states and/or counting in Gray Code, therefore, proceed from one state to the next state as one proceeds through the state diagram and down Table 1 (the Gray Code table). The error state depicted in FIG. 1 arises when any errors are identified in going from one Gray code state to the next. In most cases, testing would not be halted upon the identification of an error but rather, the error state would be recorded for later reporting and the process would set the bits properly for the test to proceed and a next Gray code state to be entered.

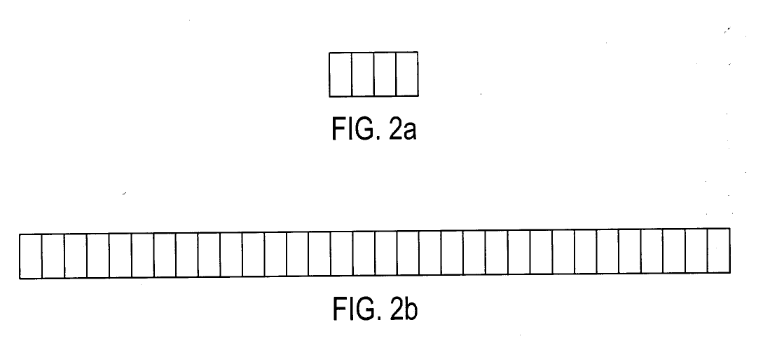

FIG. 2a is a nibble of a data word, where a nibble in the present example is a group of four bits. Since a byte is eight bits, a half byte or nibble is almost always four bits. While other groupings of bits (e.g., two bits, six bits, 8 bits (byte)etc.) will also work for purposes of the testing described herein, a four bit nibble is convenient because it takes four bits to represent a hexadecimal (hex) digit and most data words are a multiple of four bits or one hex character. For example, a 32 bit word is eight hex (four bit) characters. However, a six bit grouping/data segment would be five hex characters and an extra two bits. Typically, CAM words are between 96 and 160 bits. While a 96 bit word would easily accommodate either hex (4 bit) characters or six bit data segment, a160 bit word would not easily accommodate a six bit data segment. Any grouping of bits (bit structure or data segment) could be used to generate a Gray code state diagram used for the testing described herein, up to and including an entire word. Nibbles will be used as the exemplary data segment. Nibbles will be labeled from right to left. That is bit 0 is the rightmost bit of a nibble, followed by bit 1, followed by bit 2 and ending with bit 3. Eight nibbles make up the word shown in FIG. 2b, where a word is 32 bits as an exemplary word length. Typically whole words of a CAM will not be compared/matched/tested but rather smaller units that make up the words, such as the nibbles, will be tested. For example, if a whole word of a conventional CAM is tested a 32 bit Gray Code would be needed, which translates to 2³² states. Similarly, if all 2³² possible values of a word (in binary) were to be tested sequentially, the time would be on the order of 2³³ cycles using one cycle for each test (using a 32 bit mask with multiple bits masked) and one cycle for each set/clear with multiple bits being set/cleared in each such set/clear cycle. While the invention contemplates using Gray Codes for entire words, a more preferred aspect of the invention is using Gray coded nibbles. Using a nibble, a finite state machine for stepping through the Gary codes would require only the 16 states shown in Table 1 and FIG. 1 and a 4-bit mask.

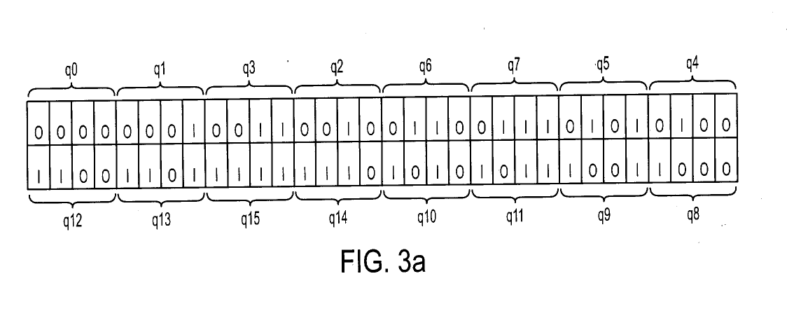

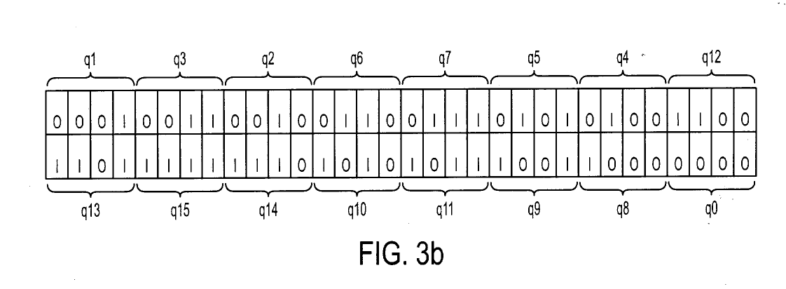

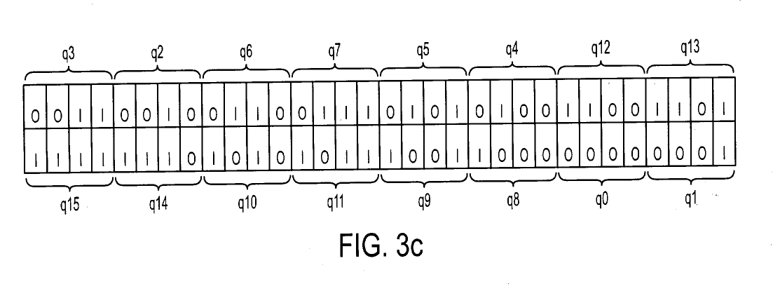

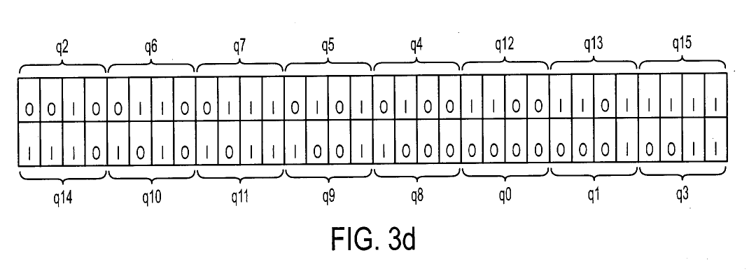

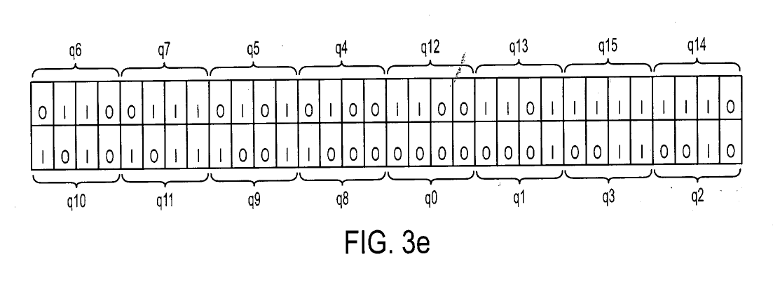

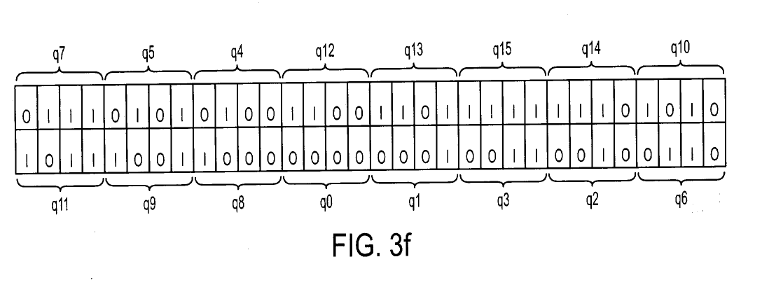

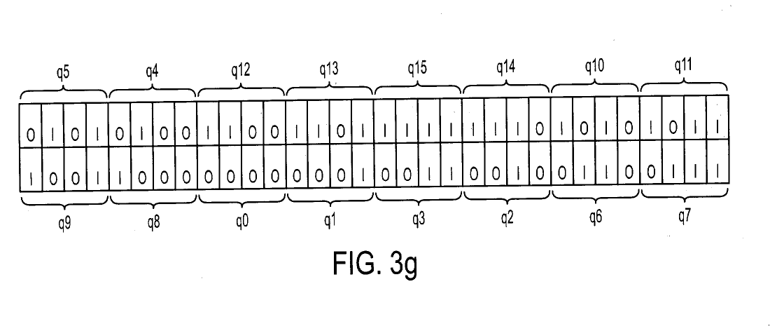

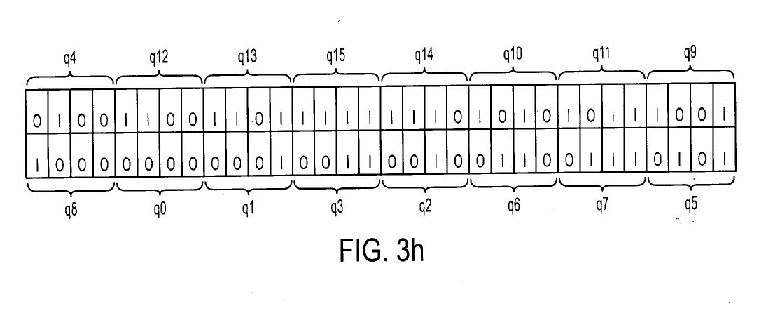

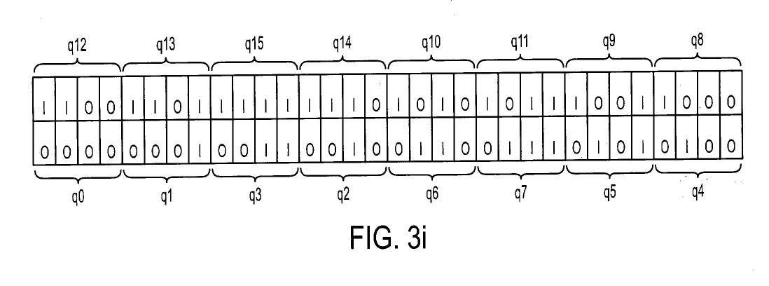

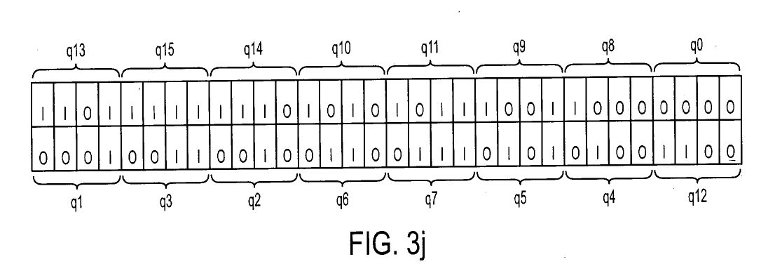

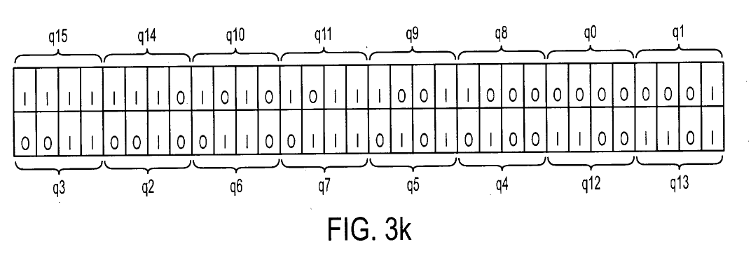

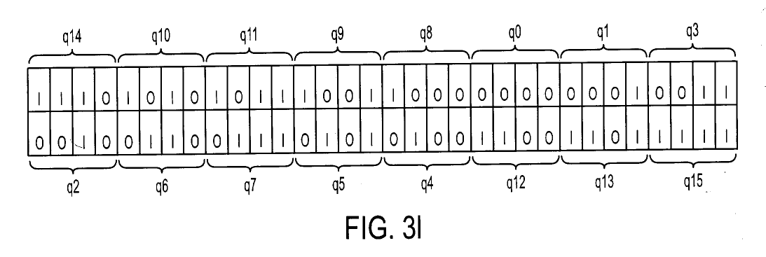

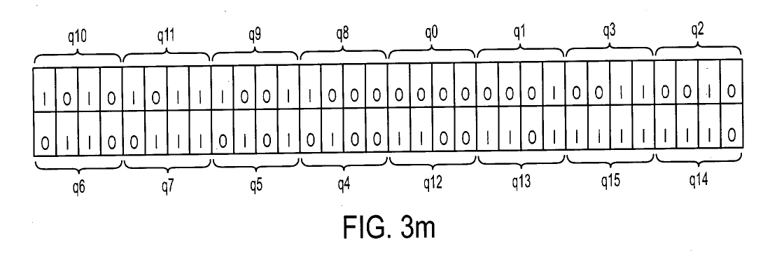

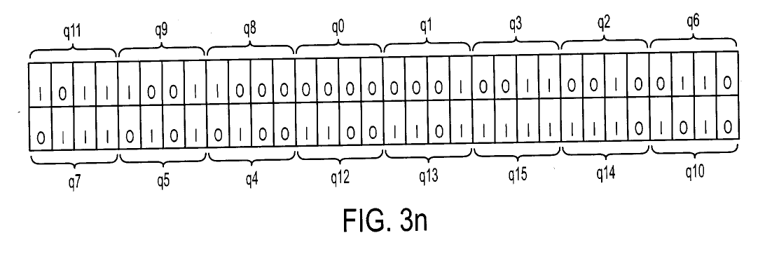

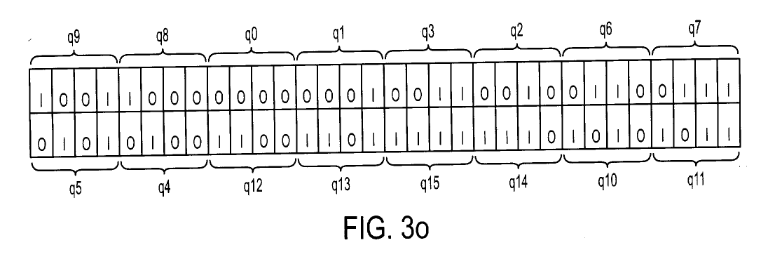

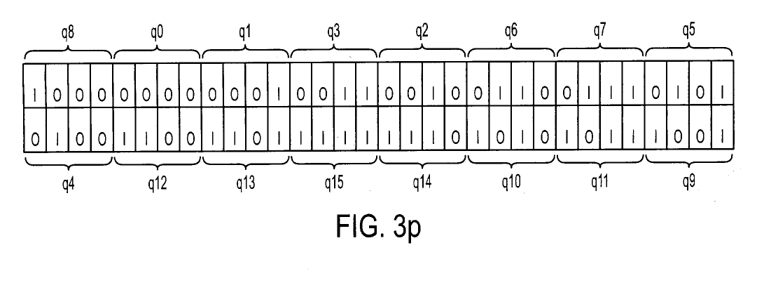

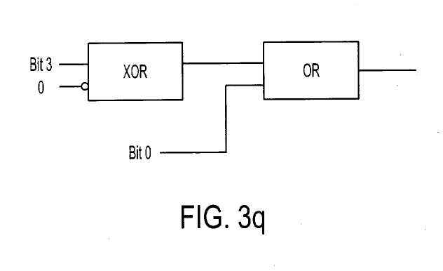

FIGS. 3a-3p show two successive 32 bit words as the data in the words proceeds from one state to the next as various bits of nibbles are tested and set. In the first (leftmost, high order) nibble of the first word of FIG. 3a is Gray Code “0000” or state “q0”. The next nibble of the first word of FIG. 3a is Gray Code “0001” or “q1”. The next nibble of the first word of FIG. 3a is Gray Code “0011” or “q3” and so on. The first nibble of the second word of FIG. 3a is Gray Code “1100” or “q12”. The next nibble is Gray Code “1101” or “q13” and so on. The data in each nibble proceeds from one state to a next state corresponding to the Gray code finite state machine depicted in FIG. 1. For example, the first (highest order) nibble of the first 32 bit word depicted in FIGS. 3a-3p starts in state q₀ and proceeds from there in accordance with the state diagram depicted in FIG. 1. The first nibble of the second 32 bit word depicted in FIGS. 3a-3p starts in state q₁₂ and proceeds from there in accordance with the state diagram depicted in FIG. 1. The above is possible because the finite state diagram/machine is cyclical. That is, no matter which state the data in a nibble starts in, as the data proceeds through the finite state diagram/machine, it will return to itself. If the data in a particular nibble starts in state “q3” then it will return to state “q3”. If the data in another particular nibble states in state “q12” then it will return to state “q12”. Since there are a limited number of states for a Gray coded nibble (sixteen) and the finite state diagram/machine is cyclical, all states are represented by the single state diagram/machine depicted in FIG. 1 and each nibble must start in one of the states of the state diagram/machine of FIG. 1 and proceeds from its initial state to the next state until it returns to its initial state, at which time the test is complete.

For example, the first nibble of the first word in FIG. 3a is initially set or loaded with Gray Code data “0000”. Assuming all bits are loaded correctly and that there are no errors in the circuitry comprising that memory cell or cells, the data in the first nibble would proceed to state “q1” represented by Gray Code “0001” and shown as the first nibble of the first word of FIG. 3b. Proceeding from one Gray Code state to the next Gray Code state requires reloading the CAM with the data for the next state for each nibble of each CAM word being tested. Once again, assuming no errors are identified, the data in the first nibble would proceed to state “q3” represented by Gray Code “0011” and shown as the first nibble of FIG. 3c. The testing of the first nibble would thus proceed through the finite state diagram until it returned to “q0” represented by Gray Code “0000”. That is, each nibble is tested and if no errors are detected then the data for the next state is concurrently reloaded for all nibbles. If errors are detected then the error state records the errors for later reporting, and specifies how the bits are to be set for the next state so that testing can proceed. For example, if the error state determines that the proper next state cannot be entered because of the particular error detected then the data in the nibble will be set to an appropriate state for the testing to proceed. Thus, testing a CAM using Gray coded nibble would result in reloading the CAM only sixteen times as opposed to reloading the equal to the number of bits in a CAM word, which may be 96 bits or more.

The second nibble of the first word of FIG. 3a would be loaded with Gray Code “0001” representing “q1” and it would proceed as above starting, however, in state “q1”. That is, the second nibble of the first word would proceed to “q3” as shown in FIG. 3b and then to “q2” represented by Gray Code “0010” and shown in FIG. 3c. Similarly for each nibble in the first word. Each nibble of each word of the CAM would proceed as described above.

It should also be noted that each adjacent nibble differs from the preceding nibble in a single bit. That is, the first nibble of FIG. 3a differs from the second nibble of FIG. 3a by a single bit and the two words (16 nibbles) represent all sixteen possible states of the finite state machine/diagram. In a total of sixteen states, all four bits of each nibble of each word in memory are with all possible combinations of bit patterns. This could also allow for additional nibble/word testing algorithms in addition to those described herein.

Referring now to Table 2, each state of the finite state machine/diagram is set out separately to understand what is being done in each state. Setting a bit means that the value of the bit is set to “1” and clearing a bit means that the value of the bit will be “0”.

TABLE 2

| State | Process |
|---|---|
| q0 | If bit 3 = 0 then set bit 0; else error. |
| q1 | If bit 0 = 1, then set bit 1; else error. |
| q3 | If bit 1 = 1, then clear bit 0; else error. |
| q2 | If bit 0 = 0, then set bit 2; else error. |
| q6 | If bit 2 = 1, then set bit 0; else error. |
| q7 | If bit 0 = 1, then clear bit 1; else error. |
| q5 | If bit 1 = 0, then clear bit 0; else error. |
| q4 | If bit 0 = 0 then set bit 3; else error. |
| q12 | If bit 3 = 1 then set bit 0; else error. |
| q13 | If bit 0 = 1, then set bit 1; else error. |
| q15 | If bit 1 = 1, then clear bit 0; else error. |
| q14 | If bit 0 = 0, then clear bit 2; else error. |
| q10 | If bit 2 = 0, then set bit 0; else error. |
| q11 | If bit 0 = 1, then clear bit 1, else error. |
| q9 | If bit 1 = 0, then clear bit 0, else error. |
| q8 | If bit 0 = 0, then clear bit 3, else error. |

The finite state machine depicted in FIG. 1, which works as described above may be implemented in software or hardware. As testing progresses from one Gray code state of the finite state machine to the next, a single bit is tested and a single bit is set unless there is an error. The bit set/cleared in a given state is the bit tested in the next state. For example, in state q0, bit 3 is tested to see if it is a “0” and if it is then bit 0 is set to “1” and the testing moves to state q1, where bit 0 is once again tested because in the preceding state (q0) it was set. In state q1, bit 1 is set to “1”. Testing then proceeds to state q3, where bit 1 is tested to see if it is a “1” because in the preceding state (q1) bit 1 was set. In state q3, bit 0 is then cleared. It is important to note that only between one and sixteen masks each masking only one bit are needed as described above. Further, as each nibble progresses from one Gray Code state to the next, each word of the CAM is reloaded with the next state information/data from one of the states of the Gray Code finite state machine or from the error processor of the finite state machine.

Each nibble has its own copy of the sixteen state finite state machine/diagram with each nibble being one state ahead of its predecessor and one state behind its successor. This also means that other nibbles in the entire memory device are in the same state at the same time (given no errors). As described above, a single bit of the data in any given nibble is tested and based on the results of that test cycle, a second bit of the data in that nibble is set or cleared (set/clear cycle). Assuming that a test cycle is different than a set/clear cycle, it would take only 32 cycles to completely test a memory device—sixteen test cycles and sixteen set/clear cycles—because all nibbles in the entire memory device could be tested concurrently. This represents a significant reduction in the time and, therefore, cost of testing a memory device, in particular a CAM.

Each state of the Gray Code state diagram/machine described herein could be implemented by a two gate processor circuit (assuming no errors) using a combination of AND, OR, XOR, NAND and/or NOR gates. Error control may dictate additional gates. Overall, however, since each state of the Gray Code state diagram/machine described herein tests only one bit of a nibble and sets/clears only one bit of a nibble, the circuitry is relatively straightforward. FIG. 3q is an exemplary implementation of Gray Code state 0 (q0) assuming no errors or error checking. Bit 3 is an input to an exclusive or (XOR) gate, as is the ‘0’ that bit 3 is tested against. Using an XOR gate means that the ‘0’ must be negated (set to ‘1’). The result of the XOR gate is true (1) if bit 3 is a ‘0’. This result is input to an OR gate, which is used to set bit 0. Each of the remaining fifteen Gray Code states may be similarly implemented using appropriate basic gates selected from AND, OR, XOR, NAND and/or NOR gates or any equivalent thereto. The circuitry for each state of the Gray Code state diagram/machine described herein may be implemented as an application specific integrated circuit (ASIC); a conventional computer or computer system; a reduced instruction set computer (RISC); any combination of hardware, software or firmware; a field programmable gate array (FPGA); any equivalent of the above; or any combination thereof.

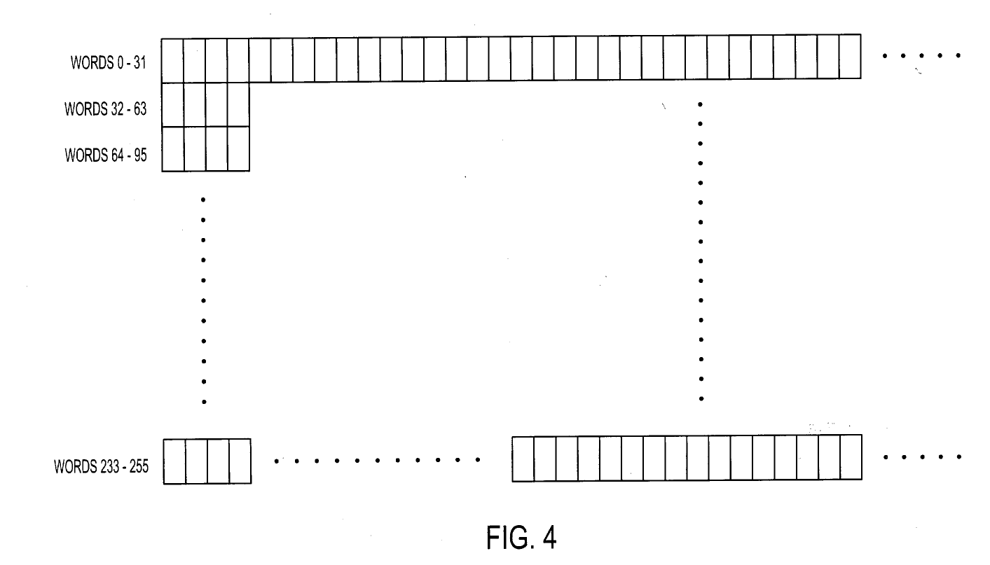

FIG. 4 is an exemplary layout of a memory device, such as a CAM. The exemplary memory may be 32 words (256 nibbles) wide by 256 nibbles long/deep. That means that the memory device would be about 65 k nibbles or about 260 k bits. Each nibble would be addressed using an eight bit column address and an eight bit row address. Memory devices could be larger or smaller or cascaded.

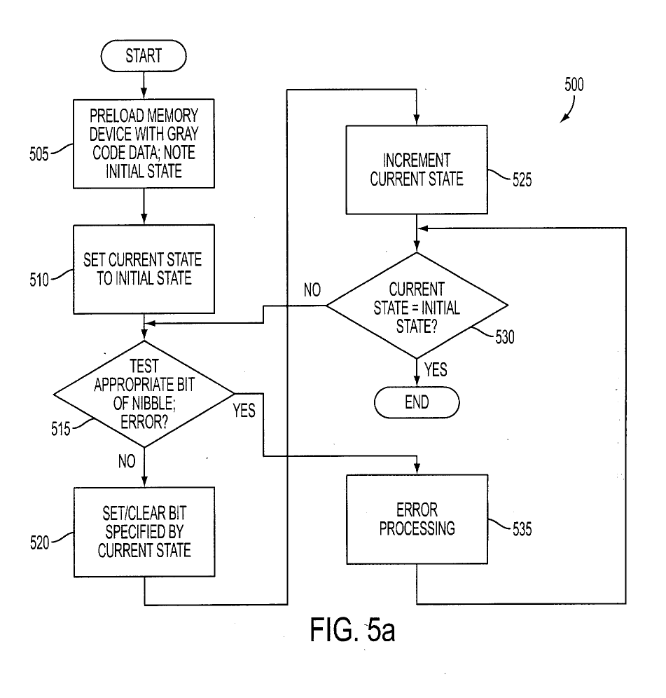

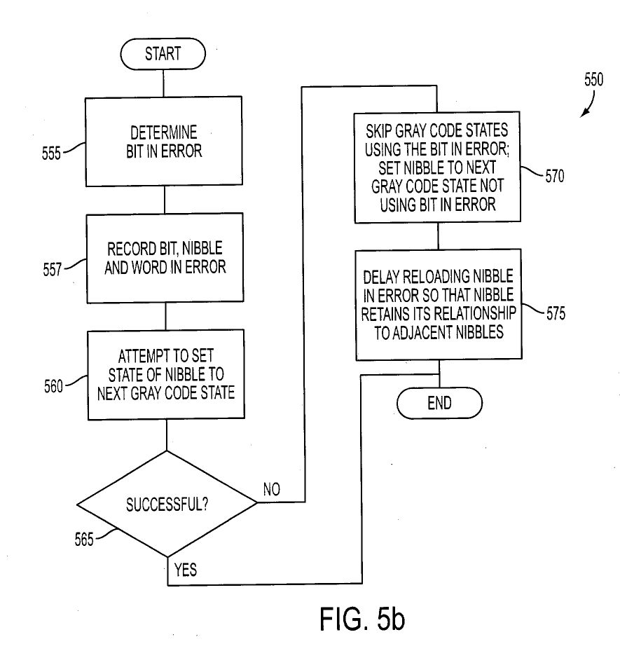

FIG. 5a is a flowchart of the method 500 for testing a CAM in accordance with the present invention. Method 500 would be practiced for each nibble of each word of a memory device, e.g., CAM, of the present invention. Gray code data is preloaded into each nibble at step 505 and the initial state of the data in each nibble is noted. At step 510 and the current state is set to the initial state. Based on the initial state of the nibble, the appropriate bit is tested at step 515. If an error is not encountered, then the appropriate bit is set or cleared at step 520 and the current state is incremented to the next (Gray Code) state at step 525. The current state is compared to the initial state at step 530 if the test has cycled back to the initial state, then all possible values have been tested for the nibble under test (and thereby all nibbles). Should an error have been identified at step 515, then error processing 535 would be as described above.

FIG. 5b is a flowchart of method 550 for the error processing 535 of method 500 depicted in FIG. 5a. The error state would identify the error and its location within the nibble at step 555, within the word and within the entire memory device being tested, record the above information at step 557 and then place the nibble in condition to continue with the test at the next state at step 560. For example, an error in state q3 with bit 1 would be recorded and an attempt would be made to place the nibble in state q2 for testing to proceed. If this is not possible as determined by the test at step 565, then an attempt is made to put the nibble in state q4 bypassing states q2-q5, which use bit 1, for example, at step 570. Should the same bit be identified in error at q15 then, once again, that error is recorded and an attempt is made to proceed to state q14. Should that not be possible, an attempt is made to proceed to state q9. It should be noted that in order to keep successive nibbles different from each other by only one bit, if such is desired, the error routine could cycle in a hold state until the adjacent nibbles caught up with the nibble in error for which certain states were bypassed at step 575.

It be may desirable not to have to keep track of nibbles starting (and thus progressing through) in a variety of Gray code states. In an alternative exemplary embodiment, each nibble of the entire CAM is set to, for example, Gray Code state q0 or Gray Code state q15. This would result in the same initial Gray code state for each nibble. Once set the nibbles proceed from one Gray code state to the next as described above.

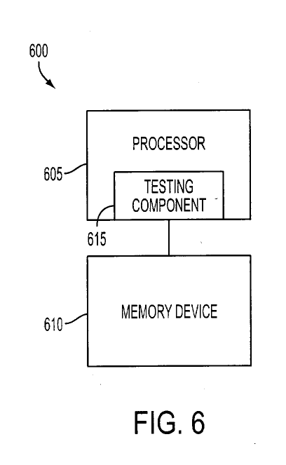

FIG. 6 is a block diagram of a system 600 for testing a memory device. System 600 includes a processor 605 coupled to a memory device 610, which may be a CAM and a testing component 615, which is part of the processor 605. The processor loads the data segments of the memory storage locations of the memory device with Gray code data. The Gary code data may differ between adjacent data segments by one bit as described above with reference to FIGS. 1-5 or may be the same Gray code data for all data segments. The testing component compares the Gray code data of each segment with a predetermined Gray code pattern for an expected result and identifies any errors if the expected result is not obtained. The processor re-writes the Gray code data of the data segment with other Gary code data representing a next Gray code state and re-tests the memory storage locations by performing comparison with another predetermined Gray code pattern for another expected result and identifies any errors if the “another” expected result is not obtained. Testing proceeds until all Gray code states of the data segment have been tested. All data segments may be test simultaneously and all memory storage locations may be tested simultaneously. As described with reference to FIGS. 1-5 a data segment may be a nibble.

In another alternative embodiment, the present invention may be used to test a priority encoder of a CAM. A priority encoder is a device with a plurality of inputs (N+1), wherein each of the inputs has an assigned priority. Typically in a priority encoder, the input IN0 is assigned the highest priority, and the priority level descends linearly as the number (location) of the input increases. Input INn thus has the lowest priority.

A CAM is typically used as a search engine wherein a match is sought between the data in the comparand register, and data stored in each word in the CAM. The CAM then outputs the address of the word in the CAM that matches the comparand. In a CAM however, more than a single word may match the comparand, but the CAM needs to indicate the address of only one of the matching words.

The priority encoder identifies the highest priority active input on the match lines of the CAM. Even if several inputs are simultaneously active, the priority encoder will only indicate the activity of the input with the highest priority. The priority encoder is used in the CAM as the means to translate the position (within the CAM) of a matching word, into a numerical address representing that location. The priority encoder is also used to only translate the location of one word (the highest priority word), and ignore all other simultaneously matching words.

A typical priority encoder is comprised of two blocks. The first block is called the “highest priority indicator”, and is followed by the “address encoder” block.

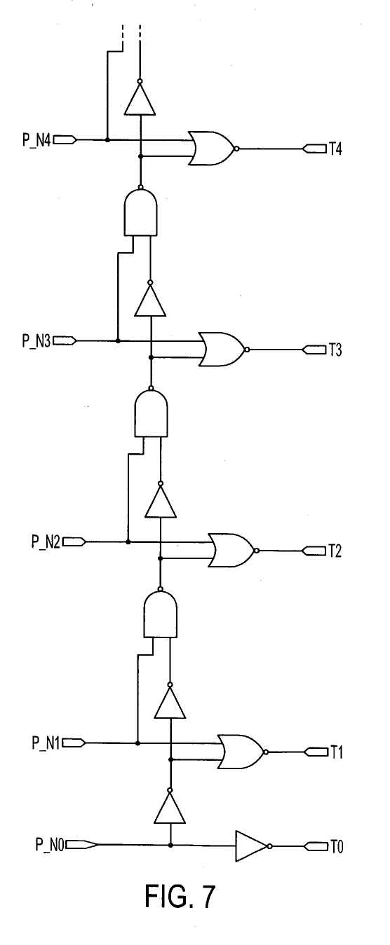

The structure and operational details of an exemplary priority encoder are described in U.S. patent application Ser. No. 10/188,971, entitled “NOVEL PRIORITY ENCODER” filed Jul. 5, 2002 by Zvi Regev, which is incorporated in its entirety herein by reference. FIG. 7 shows an exemplary embodiment of the highest priority indicator block. In the initial state all the inputs P_N0, . . . , P_N4 are at a state of “1” which is the inactive state, while all the outputs T0-T4 are in the inactive state of “0”. Whenever any input goes to the active state of “0”, the output associated with this input becomes active as well, and goes to the state of “1”. Consequently, an active input also disables all the inputs above it in the chain, forcing their associated outputs to remain inactive (“0”). The priority level in the structure is shown in FIG. 7. The bottom of the priority encoder shown has the highest priority, and the priority descends toward the top. Therefore, if any number of inputs are simultaneously active, the highest priority indicator will activate only the output associated with the highest priority active input, leaving all other outputs inactive, thus indicating the highest priority activity.

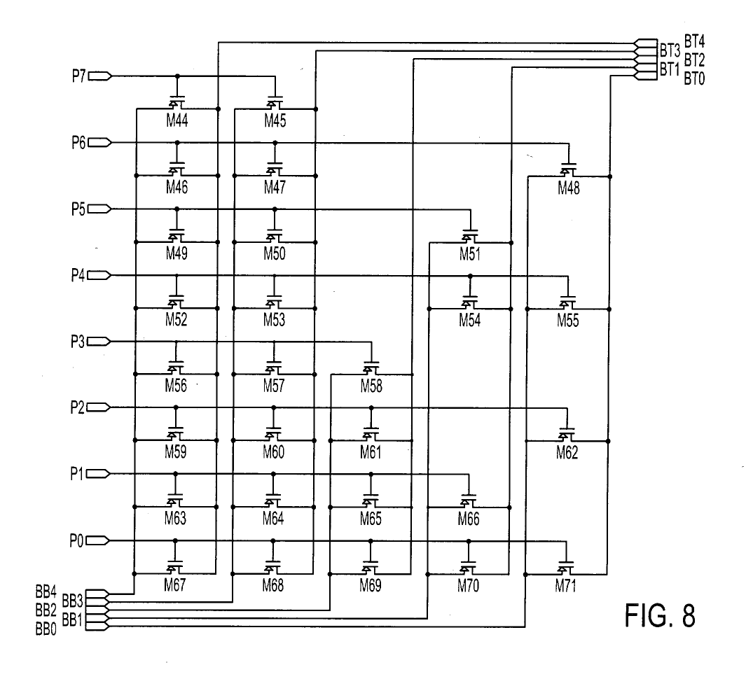

Many methods are used to convert the output of the highest priority indicator into a numerical value. The simplest method is that of a look-up table. FIG. 8, shows an eight-bit section of a 32 input look-up table. To understand its operation, consider that all the inputs BB0 through BB4, are connected to ground, and the pins marked as BT0 through BT4, are each connected to the power supply via a separate resistor and collectively provide an output address. Now assume that the input P0 is “1”, turning ON all the transistors connected to this line. The resulting current through the turned ON transistors, causes the voltage at the pins BT0 through BT4 to go down to zero volts providing an output address 00000. If instead the input P3 is active, only the outputs BT2, BT3, and BT4, go to 0 volts and the output address is 00011.

The CAM considered in the present invention supports a comparand containing a ‘0’, ‘1’, or ‘X’ (don't care) for each bit. A ‘0’ will match only a zero in the entries compared. A ‘1’ will match only a one in the entries compared. An ‘X’ will match either a zero or a one. Implementations of both binary and ternary CAMs can have this type of a comparand implementation, but not all binary or ternary CAMs do. The CAM is arranged so that the comparator at every entry has a single “match” indicator going to the priority encoder. The priority encoder has a plurality of “match” inputs, each one from a different entry in the CAM noted earlier as the N+1 input. The priority encoder outputs the “address” of one matching entry or a “no-match” indication if no “match” input is set to “true”. The priority encoder is constructed such that each “match” input has a fixed address and priority and the inputs are labeled to indicate the address and the priority in the format “match[x]”, where x indicates both the address and the priority. Lower addresses have higher priority. If more than one match is indicated, it is always the “highest-priority” match that is output by the priority encoder. Match[0]” is the highest priority match indication input. “Match[N]”, where N is the number of words in the CAM, is the lowest priority match indication input.

Further details of a priority encoder can be found in U.S. patent application Ser. No. 10/188,971 referenced earlier.

Testing a priority encoder requires testing all possibilities of a single match and at least adjacent entry multiple matches. When only a single entry should match, the “match-output” should be indicated and the “multi-match output” must not be indicated. When two or more entries match, both the “match-output” and “multi-match output” must be indicated. Since almost all of the defects in a CAM priority encoder occur between two adjacent entries in the priority encoder, it is sufficient to test a condition where every two adjacent entries are the only ones that match. Whether this condition holds true is a function of the design of the CAM.

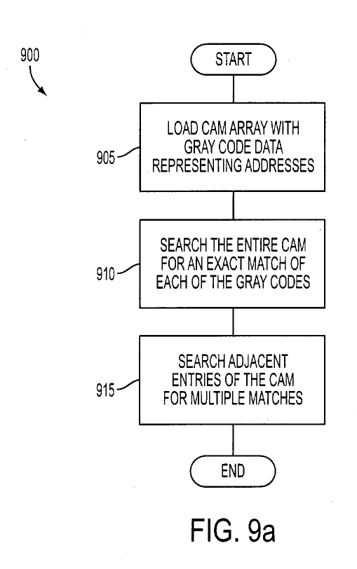

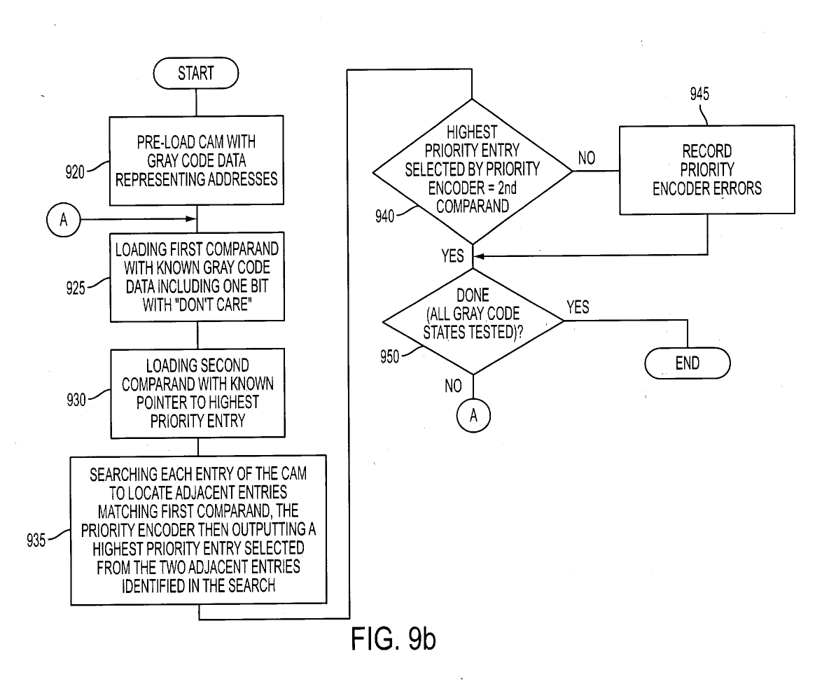

Although testing of a priority encoder contemplates using a Gray code of 96 or more bits commensurate with the size of typical CAM memory storage locations, for ease of discussion and explanation, a four bit Gray code is used as an example. FIG. 9a illustrates an exemplary method for testing the priority encoder of a CAM using the present invention. At step 905 the memory storage locations of the CAM are loaded with known Gray code data representing addresses/memory storage locations of the CAM. For example, in address #15 (1111 binary) Gray code data 1000, Gray code equivalent of 1111 binary, would be loaded. That is, each address/memory storage location/data word of the CAM is loaded with the Gray code representation of its binary address. Each data word/memory storage location of the CAM is loaded with a known Gray code address and the comparand is also loaded with the same known Gray code. Assuming that the location with the Gray code address is located by the priority encoder and only that location is found then the highest priority location having that Gray code is properly identified. By loading each memory storage location of the CAM with a different Gray code (different by one bit from each of its neighbors/adjacent memory storage locations) and searching the CAM for each Gray code successively, it is possible to test the CAM without reloading the CAM but rather reloading the comparand with successive Gray codes, each search finding the highest priority memory storage location in the CAM. In testing the memory storage locations of the CAM, nibbles were used as described above with reference to FIGS. 1-5. In testing the priority encoder of the CAM, each memory storage location of the CAM will be loaded with a Gray code representing the binary address of the memory storage location.

At step 910 the entire CAM array is searched for an exact (single) match of each of the Gray codes. For each pass of the search, the priority encoder should output the binary address corresponding to the Gray code specified, with the “match-output” indicated and the “multi-match output” NOT indicated. (If a “multi-match output” is detected by the priority encoder, then there is clearly an error because each and every data word/storage location of the CAM should be different and represent its binary address in Gray code.) The first pass of the search indicated at step 910 would be for “0000 . . . ”, where “0000 . . . ” will be the Gray code for the first data word of the CAM using the number of bits required to Gray code the address of that location. For example, if a CAM has 65 k 32-bit words, then it would require sixteen bits to uniquely address each word. The priority encoder will return address of “0000 . . . ” with a match set/indicated and multi-match not set/indicated. The next Gray code searched for would be “. . . 0001”, then “. . . 0011”, etc. This sequence guarantees that every match entry operates properly and that the priority encoder returns the correct data.

With the Gray code data in the CAM remaining unchanged, at step 915, combinations of two adjacent entries are searched. For example, searching for “000X” should match both entries 0 and 1. The priority encoder will return the address “0000” (highest priority address), and both “match output” and “multi-match output” should be set/indicated. The next pass of the search indicated at step 915 would be for “00X1”. This should match entries 1 and 2. The address output should be “0001”, with both match and multi-match set/indicated. Table 3 shows the word number, the binary address of the word number, the Gray Code content of the binary address, the comparand that would be used for each of the adjacent entries, the priority address and the words with Gray Code data that are compared using the comparand.

The search undertaken at step 915 tests multiple matches on adjacent words only. For random multiple matches throughout the CAM address range, some words may have to be rewritten. If, however, a quasi-random test, wherein a “don't care” bit is placed on any of the most significant bits is sufficient, then the quasi-random test could be conducted without any changes to the loaded Gray Code data.

TABLE 3

| | | | | | Compares |
|---|---|---|---|---|---|
| Word | Binary | Gray Code | | | Gary Code |
| Number | Address | content | Comparand | Priority | content of Word |
| 0 | 0000 | 0000 | 000X | 0 | 0 and 1 |
| 1 | 0001 | 0001 | 000X | 0 | 0 and 1 |
| 2 | 0010 | 0011 | 00X1 | 1 | 2 and 1 |
| 3 | 0011 | 0010 | 001X | 2 | 2 and 3 |
| 4 | 0100 | 0110 | 0X10 | 3 | 3 and 4 |
| 5 | 0101 | 0111 | 011X | 4 | 4 and 5 |
| 6 | 0110 | 0101 | 01X1 | 5 | 5 and 6 |
| 7 | 0111 | 0100 | 010X | 6 | 6 and 7 |
| 8 | 1000 | 1100 | X100 | 7 | 7 and 8 |
| 9 | 1001 | 1101 | 110X | 8 | 8 and 9 |
| 10 | 1010 | 1111 | 11X1 | 9 | 9 and 10 |
| 11 | 1011 | 1110 | 111X | 10 | 10 and 11 |
| 12 | 1100 | 1010 | 1X10 | 11 | 11 and 12 |
| 13 | 1101 | 1011 | 101X | 12 | 12 and 13 |
| 14 | 1110 | 1001 | 10X1 | 13 | 13 and 14 |
| 15 | 1111 | 1000 | 100X | 14 | 14 and 15 |

Table 3 is a simplified version of what would be required for priority encoder testing. Table 3 includes the Gray code data for four bits only to simplify the discussion. As indicated to test a 65 k word memory a sixteen bit address would be required. A sixteen bit Gray code table would be quite large to represent in a table so a four bit Grey code table is used in this example to illustrate the invention. Step 915 tests adjacent entries of the CAM array. The use of Table 3 will be described by example. The first/leftmost column indicates the word number and the second column indicates the binary equivalent of the word number indicated in the first column. The third column indicates the Gray Code content of the word number. That is, the content of binary address “0000” is “0000”. The content of binary address “0111” is “0100”. Using comparand “000X” would compare the content of words 0 and 1, where word 0 holds Gray Code “0000” and word 1 holds Gray Code “0001”. This is indicated in the last column of Table 3. The lower address has the higher priority so the priority address is word 0 as indicated in the fifth column of Table 3. Comparand “010X” would compare the contents of words 6 and 7, where word 6 holds Gray Code “0101” and word 7 holds Gary Code “0100”. This is indicated in the last column of Table 3. Word 6 has the higher priority address as indicated in the fifth column of Table 3. In all cases only one comparand bit ever has a value ‘X’ in this test.

In the above example and FIG. 9a, no error processing is indicated for simplicity and ease of understanding. It is understood, however, that error processing exists and consists of recording any errors identified at all steps such that further action can be taken upon completion of the tests or during the tests.

The above example is illustrative only. In a typical CAM memory the number of bits in a word ranges from 96 to 160 or even perhaps greater. A 256 k entry CAM memory array would, for example, require eighteen bits to address the entries of the CAM (2¹⁸=262,144=256 k). Thus, the address range that can be tested using the present invention is very large.

Thus, testing a priority encoder of a CAM is accomplished as depicted in FIG. 9b by pre-loading a CAM with known Gray Code data at step 920, where the Gray Code data is arranged in the CAM so that each entry of the CAM differs from an adjacent entry by a single bit. A first comparand is also loaded (or set) with a known Gray Code at step 925. A second comparand of the CAM is loaded with a pointer to the highest priority entry at step 930. A search of the CAM is then performed by comparing each entry of the CAM against the first comparand at step 935. The search should result in the location and identification of two adjacent entries matching the first with only the highest priority entry returned by the priority encoder. The highest priority entry returned by the priority encoder is compared against the second comparand containing the known pointer to the highest priority entry at step 940 to determine if the priority encoder is functioning properly. This process is performed repeatedly without reloading the CAM but simply by cycling the comparands through all of the Gray Code states. Specifically, step 950 tests to see if the test is complete/done by checking if all Gray Code states have been tested. Step 945 records any priority encoder errors identified by step 940.

A system for testing a priority encoder of a CAM would retain the coupling of a processor with the CAM as depicted in FIG. 6 to carry out the tests described herein with reference to FIGS. 7-9. Specifically, a processor is coupled to the CAM, which has a priority encoder. The processor stores a respective predetermined Gray code in at least two adjacent memory storage locations of the CAM, with the Gray code of each memory storage location differing from the Gray code of the adjacent memory storage location by one data bit. A testing component within the processor compares the predetermined Gray code stored in the adjacent memory storage locations with a predetermined Gray code pattern having a bit of the predetermined Gray code pattern masked in the expectation that a highest priority match output is the result. An error is identified if the expected highest priority match output is not obtained. A plurality of memory storage locations of the CAM may be tested simultaneously. Each of the memory storage locations of the CAM are tested further by comparing the predetermined Gray code stored in each of the memory storage locations with a predetermined Gray code pattern which has the one data bit which differs between adjacent memory storage locations set to “don't care” in the expectation of obtaining a highest priority match output. Finally, each of the memory storage locations of the CAM are tested by comparing the predetermined Gray code stored in each of the memory storage locations with a predetermined Gray code pattern which has a most significant bit set to “don't care” in the expectation of receiving a highest priority match output. In each case where a highest priority match output is expected and not received, an error is identified and recorded.

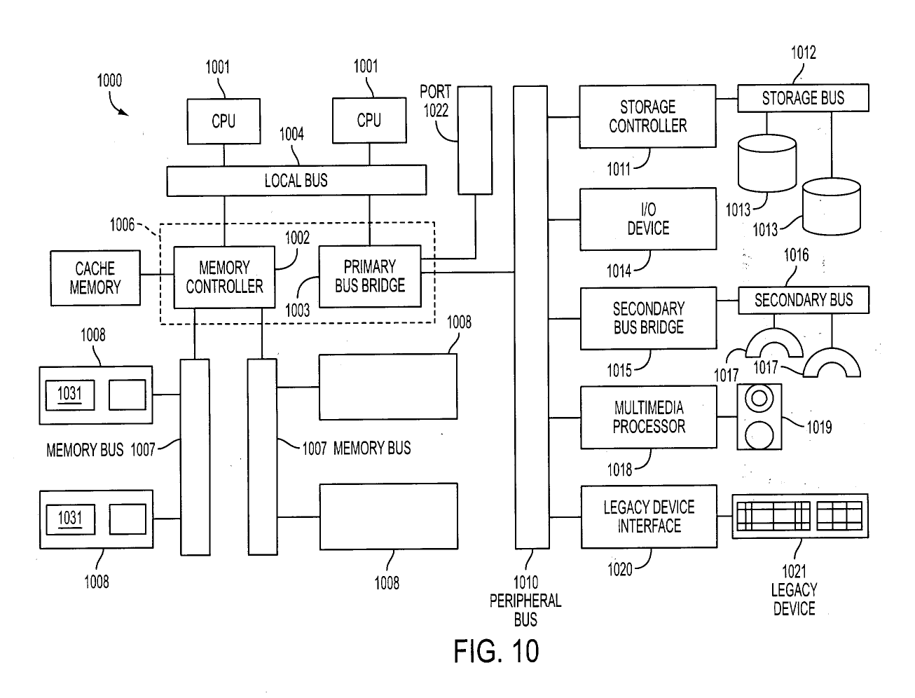

FIG. 10 illustrates an exemplary processing system 1000 which may be used to test a CAM in accordance with the invention. The processing system 1000 is a more complicated than the arrangement depicted in FIG. 6 but retains the coupling of a processor with the CAM memory to carry out the tests described herein. Processor 1000 includes one or more processors 1001 coupled to a local bus 1004. A memory controller 1002 and a primary bus bridge 1003 are also coupled the local bus 1004. The processing system 1000 may include multiple memory controllers 1002 and/or multiple primary bus bridges 1003. The memory controller 1002 and the primary bus bridge 1003 may be integrated as a single device 1006.

The memory controller 1002 is also coupled to one or more memory buses 1007. Each memory bus accepts memory components 1008 including at least one CAM device for testing. A processor circuit of the present invention may be used in conjunction with CAM 1008. The processor circuit may be used to test both memory locations of CAM 1008 and a priority encoder of CAM 1008 in accordance with any of the embodiments of the present invention disclosed above in connection with FIGS. 1-9. The processor circuit may operate via an input/output port (e.g., I/O device 1014) interface with CAM 1008 to test CAM 1008 and a priority encoder of CAM 1008 or operate entirely within the processing system as built-in-test-equipment (BITE) to test CAM 1008 and a priority encoder of CAM 1008. For example, device 1031 may be a processor circuit (BITE) used to test CAM 1008 and a priority encoder of CAM 1008. The processor circuit may be coupled directly to CAM 1008 and a priority encoder of CAM 1008. The memory components 1008 may be arranged on a memory card or a memory module. Examples of memory modules include single inline memory modules (SIMMs) and dual inline memory modules (DIMMs). The memory controller 1002 may also be coupled to a cache memory 1005. The cache memory 1005 may be the only cache memory in the processing system. Alternatively, other devices, for example, processors 1001 may also include cache memories, which may form a cache hierarchy with cache memory 1005. If the processing system 1000 include peripherals or controllers which are bus masters or which support direct memory access (DMA), the memory controller 1002 may implement a cache coherency protocol. If the memory controller 1002 is coupled to a plurality of memory buses 1007, each memory bus 1007 may be operated in parallel, or different address ranges may be mapped to different memory buses 1007.

The primary bus bridge 1003 is coupled to at least one peripheral bus 1010. Various devices, such as peripherals or additional bus bridges may be coupled to the peripheral bus 1010. These devices may include a storage controller 1011, an miscellaneous I/O device 1014, a secondary bus bridge 1015, a multimedia processor 1018, and an legacy device interface 1020. The primary bus bridge 1003 may also coupled to one or more special purpose high speed ports 1022. In a personal computer, for example, the special purpose port might be the Accelerated Graphics Port (AGP), used to couple a high performance video card to the processing system 1000.

The storage controller 1011 couples one or more storage devices 1013, via a storage bus 1012, to the peripheral bus 1010. For example, the storage controller 1011 may be a SCSI controller and storage devices 1013 may be SCSI discs. The I/O device 1014 may be any sort of peripheral. For example, the I/O device 1014 may be an local area network interface, such as an Ethernet card. The secondary bus bridge may be used to interface additional devices via another bus to the processing system. For example, the secondary bus bridge 1016 may be an universal serial port (USB) controller used to couple USB bus devices 1017 via to the processing system 1000. The multimedia processor 1018 may be a sound card, a video capture card, or any other type of media interface, which may also be coupled to one additional devices such as speakers 1019. The legacy device interface 1020 is used to couple legacy devices, for example, older styled keyboards and mice, to the processing system 1000.

The processing system 1000 illustrated in FIG. 10 is only an exemplary processing system with which the invention may be used. While FIG. 10 illustrates a processing architecture especially suitable for a general purpose computer, such as a personal computer or a workstation, it should be recognized that well known modifications can be made to configure the processing system 1000 to become more suitable for use in a variety of applications. For example, many electronic devices which require processing may be implemented using a simpler architecture which relies on a CPU 1001 coupled to memory components 1008 and/or memory buffer devices 1004. These electronic devices may include, but are not limited to audio/video processors and recorders, gaming consoles, digital television sets, wired or wireless telephones, navigation devices (including system based on the global positioning system (GPS) and/or inertial navigation), and digital cameras and/or recorders. The modifications may include, for example, elimination of unnecessary components, addition of specialized devices or circuits, and/or integration of a plurality of devices.

While the invention has been described and illustrated with reference to specific exemplary embodiments, it should be understood that many modifications and substitutions can be made without departing from the spirit and scope of the invention. Accordingly, the invention is not to be considered as limited by the foregoing description but is only limited by the scope of the appended claims.

What is claimed as new and desired to be protected by Letters Patent of the United States is:

1. A method of testing a memory device comprising:
storing a predetermined code in at least one memory storage location of said memory device, said predetermined code including a plurality of data segments, each data segment containing Gray code data which differs from Gray code data of an adjacent data segment by one data bit; and
testing said at least one memory storage location by comparing the Gray code data of each data segment with a predetermined Gray code pattern stored in a comparand register for an expected result.

2. The method according to claim 1, wherein said memory device is a content addressable memory (CAM) device.

3. The method according to claim 1, wherein said data segment is a nibble.

4. The method according to claim 1, further comprising identifying an error if said expected result is not obtained.

5. The method according to claim 1, further comprising:
re-writing the Gray code of each data segment with another Gray code; and
re-testing said at least one memory storage location by comparing the Gray code of each data segment with another predetermined Gray code pattern stored in said comparand register for another expected result.

6. The method according to claim 1, further comprising simultaneously testing all data segments of said at least one memory storage location.

7. The method according to claim 1, further comprising testing a plurality of memory storage locations of said memory device simultaneously.

8. The method according to claim 4, further comprising determining another Gray code data based on identification of a bit of said data segment in error.

9. A system for testing a memory device comprising:
a processor; and
said memory device coupled to said processor;
said memory device having at least one memory storage location, said processor loading said memory storage location with a predetermined code, said predetermined code including a plurality of data segments, each data segment containing Gray code data which differs from Gray code data of an adjacent data segment by one data bit; and
a testing component within said processor for comparing the Gray code data of each data segment with a predetermined Gray code pattern stored in a comparand register for an expected result.

10. The system according to claim 9, wherein said memory device is a content addressable memory (CAM) device.

11. The system according to claim 9, wherein said data segment is a nibble.

12. The system according to claim 9, further comprising identifying an error if said expected result is not obtained.

13. The system according to claim 9, wherein said processor:
re-writes the Gray code data of each data segment with another Gray code data; and
re-tests said at least one memory storage location by comparing the Gray code data of each data segment with another predetermined Gray code pattern stored in said comparand register for another expected result.

14. The system according to claim 9, wherein said processor simultaneously tests all data segments of said at least one memory storage location.

15. The system according to claim 9, wherein said processor tests a plurality of memory storage locations of said memory device simultaneously.

16. The system according to claim 12, further comprising determining another Gray code data based on identification of a bit of said data segment in error.

17. A system for testing a memory device comprising:
a plurality of circuits, each circuit corresponding to a Gray code pattern;
wherein each circuit comprises a plurality of gates;
at least one memory storage location in which is stored a predetermined code, said predetermined code including a plurality of data segments, each data segment containing a Gray code which differs from an adjacent data segment by one data bit;
a first gate of said plurality of gates operates to test a first bit of each data segment of at least one memory storage location of said memory device by comparing said first data bit of each data segment of said at least one memory storage location of said memory device against a Gray code pattern stored in a comparing device for an expected result; and
a second gate operates to identify and output an error indication if said expected result is not obtained.

18. The system according to claim 17, further comprising a third gate for updating a data segment code with another Gray code by one of setting and clearing a second data bit of said Gray code of said at least one memory storage location of said memory device in order to reload said data segment of said at least one memory storage location if said expected result is obtained and retesting said at least one memory storage location by using another of said plurality of circuits for said another Gray code.

19. The system according to claim 17, wherein said memory device is a content addressable memory (CAM) device.

20. The system according to claim 17, wherein said data segment is a nibble.

21. The system according to claim 18, further comprising simultaneously testing of all data segments of said at least one memory storage location.

22. The system according to claim 18, further comprising testing of a plurality of memory storage locations of said memory device simultaneously.

23. A method of testing a memory device comprising:
storing a predetermined code in at least one memory storage location of said memory device, said predetermined code including a plurality of data segments, each data segment containing Gray code data; and
testing said at least one memory storage location by comparing the Gray code data of each data segment with a predetermined Gray code pattern stored in a comparand register for an expected result.

24. The method according to claim 23, wherein said memory device is a content addressable memory (CAM) device.

25. The method according to claim 23, wherein said data segment is a nibble.

26. The method according to claim 23, further comprising identifying an error if said expected result is not obtained.

27. The method according to claim 23, further comprising:
re-writing the Gray code of each data segment with another Gray code; and
re-testing said at least one memory storage location by comparing the Gray code of each data segment with another predetermined Gray code pattern stored in said comparand register for another expected result.

28. The method according to claim 23, further comprising simultaneously testing of all data segments of said at least one memory storage location.

29. The method according to claim 23, further comprising testing of a plurality of memory storage locations of said memory device simultaneously.

30. The method according to claim 26, further comprising determining another Gray code data based on identification of a bit of said data segment in error.

31. A system for testing a memory device comprising:
a processor; and
said memory device coupled to said processor;
said memory device having at least one memory storage location, said processor loading said memory storage location with a predetermined code, said predetermined code including a plurality of data segment, each data segment containing Gray code data; and
a testing component within said processor for comparing the Gray code data of each data segment with a predetermined Gray code pattern stored in a comparand register for an expected result.

32. The system according to claim 31, wherein said memory device is a content addressable memory (CAM) device.

33. The system according to claim 31, wherein said data segment is a nibble.

34. The system according to claim 31, further comprising identifying an error if said expected result is not obtained.

35. The system according to claim 31, wherein said processor:
re-writes the Gray code data of each data segment with another Gray code data; and
re-tests said at least one memory storage location by comparing the Gray code data of each data segment with another predetermined Gray code pattern stored in said comparand register for another expected result.

36. The system according to claim 31, wherein said processor simultaneously tests all data segments of said at least one memory storage location.

37. The system according to claim 31, wherein said processor tests a plurality of memory storage locations of said memory device simultaneously.

38. The method according to claim 34, further comprising determining another Gray code data based on identification of a bit of said data segment in error.

39. A method for testing a priority encoder of a content address memory (CAM) device, comprising:
storing a respective predetermined Gray code in at least two adjacent memory storage locations of said CAM, said respective predetermined Gray codes representing a Gray coded address of said adjacent memory storage locations, said Gray code of each memory storage location differs from said Gray code of the adjacent memory storage location by one data bit; and
testing said memory storage locations by comparing the predetermined Gray code stored in said adjacent memory storage locations with a predetermined Gray code pattern having a bit of said predetermined Gray code pattern stored in a comparand register, said predetermined Gray code pattern being masked, for an expected highest priority match output.

40. The method according to claim 39, further comprising identifying an error if said highest priority match output is not obtained.

41. The method according to claim 39, further comprising testing of a plurality of memory storage locations of said CAM simultaneously.

42. The method according to claim 39, further comprising testing each of said memory storage locations of said CAM by comparing the predetermined Gray code stored in each of said memory storage locations with said predetermined Gray code pattern stored in a comparand register, said predetermined Gray code pattern having the one data bit which differs between adjacent memory storage locations set to “don't care” for said highest priority expected result.

43. The method according to claim 39, further comprising testing each of said memory storage locations of said CAM by comparing the predetermined Gray code stored in each of said memory storage locations with said predetermined Gray code pattern stored in a comparand register, said predetermined Gray code pattern having a most significant bit set to “don't care” for said highest priority expected result.

44. A system for testing a priority encoder of a content addressable memory (CAM) device comprising:
a processor;
said processor coupled to said CAM, said processor storing a respective predetermined Gray code in at least two adjacent memory storage locations of said CAM, said Gray code of each memory storage location differs from said Gray code of the adjacent memory storage location by one data bit; and
a testing component within said processor for comparing said predetermined Gray code stored in said adjacent memory storage locations with a predetermined Gray code pattern having a bit of said predetermined Gray code pattern stored in a comparand register, said predetermined Gray code pattern being masked, for a highest priority match output.

45. The system according to claim 44, further comprising identifying an error if said highest priority match output is not obtained.

46. The system according to claim 44, further comprising testing of a plurality of memory storage locations of said memory device simultaneously.

47. The system according to claim 44, further comprising testing each of said memory storage locations of said CAM by comparing the predetermined Gray code stored in each of said memory storage locations with said predetermined Gray code pattern stored in a comparand register, said predetermined Gray code pattern having the one data bit which differs between adjacent memory storage locations set to “don't care ” for said highest priority expected result.

48. The system according to claim 44, further comprising testing each of said memory storage locations of said CAM by comparing the predetermined Gray code stored in each of said memory storage locations with said predetermined Gray code pattern stored in a comparand register, said predetermined Gray code pattern having a most significant bit set to “don't care” for said highest priority expected result.
